(19) United States
(12) Patent Application Publication
(10) Pub. No.: US 2026/0206495 A1
(43) Pub. Date: Jul. 16, 2026

(54) MAGNETIC MEMORY DEVICE

(71) Applicant: SAMSUNG ELECTRONICS CO., LTD., Suwon-si (KR)

(72) Inventors: Jun Ho JEONG, Suwon-si (KR); Whan Kyun Kim, Suwon-si (KR); Tae Hyun Kim, Suwon-si (KR); Eun Sun Noh, Suwoin-si (KR); Hee Ju Shin, Suwon-si (KR); Joon Myoung Lee, Suwon-si (KR)

(73) Assignee: SAMSUNG ELECTRONICS CO., LTD., Suwon-si (KR)

(21) Appl. No.: 19/312,928

(22) Filed: Aug. 28, 2025

(30) Foreign Application Priority Data
Jan. 16, 2025 (KR) 10-2025-0006814

(51) Int. Cl. H10N 50/85; H10B 61/00; H10N 50/01; H10N 50/10

(52) U.S. Cl. CPC H10N 50/85; H10B 61/22; H10N 50/01; H10N 50/10

(57) ABSTRACT

A magnetic memory device may include a pinned layer pattern, a free layer pattern, a tunnel barrier layer pattern between the pinned layer pattern and the free layer pattern, an oxide layer pattern spaced apart from the tunnel barrier layer pattern with the free layer pattern interposed between the oxide layer pattern and the tunnel barrier layer pattern, a capping layer pattern spaced apart from the free layer pattern with the oxide layer pattern interposed between the capping layer pattern and the free layer pattern, a first seed layer pattern spaced apart from the tunnel barrier layer pattern with the pinned layer pattern interposed between the first seed layer pattern and the tunnel barrier layer pattern; and a second seed layer pattern between the pinned layer pattern and the first seed layer pattern. The first seed layer pattern may include a transition metal oxide.

### CROSS-REFERENCE TO RELATED APPLICATION

This application claims priority from Korean Patent Application No. 10-2025-0006814 filed on Jan. 16, 2025 in the Korean Intellectual Property Office, the disclosure of which is incorporated herein by reference in its entirety.

### BACKGROUND

### 1. Technical Field

One or more embodiments of the disclosure relate to a magnetic memory device.

### 2. Description of the Related Art

With the increasing demand for high speed performance and low power consumption in electronic devices, the memory devices integrated into the electronic devices also require rapid read/write operations and low operating voltages. Magnetic memory devices are being researched as memory devices that satisfy such a requirement. The magnetic memory devices are non-volatile, capable of operating at a high speed, and are attracting attention as next-generation memories.

As magnetic memory devices continue to advance toward highly integrated, spin-transfer torque magnetic random-access memory (STT-MRAM), which stores information using a spin transfer torque (STT) phenomenon, has emerged. The STT-MRAM may induce magnetization reversal by applying current directly to a magnetic tunnel junction element to store information. The highly integrated STT-MRAM requires high-speed operation and low current operation.

### SUMMARY

One or more embodiments of the present disclosure provide a magnetic memory device having improved product reliability and performance.

According to an aspect of the present disclosure, there is provided a magnetic memory device including a pinned layer pattern, a free layer pattern, a tunnel barrier layer pattern between the pinned layer pattern and the free layer pattern, an oxide layer pattern spaced apart from the tunnel barrier layer pattern with the free layer pattern interposed between the oxide layer pattern and the tunnel barrier layer pattern, a capping layer pattern spaced apart from the free layer pattern with the oxide layer pattern interposed between the capping layer pattern and the free layer pattern, a first seed layer pattern spaced apart from the tunnel barrier layer pattern with the pinned layer pattern interposed between the first seed layer pattern and the tunnel barrier layer pattern; and a second seed layer pattern between the pinned layer pattern and the first seed layer pattern. The first seed layer pattern may include a transition metal oxide.

According to another aspect of the present disclosure, there is provided a magnetic memory device comprising a lower electrode, an upper electrode and a magnetic tunnel junction element between the lower electrode and the upper electrode, wherein the magnetic tunnel junction element includes a first seed layer pattern, a second seed layer pattern, a pinned layer pattern, a tunnel barrier layer pattern, a free layer pattern, an oxide layer pattern, and a capping layer pattern that are stacked on the lower electrode, and the first seed layer pattern is in direct contact with the lower electrode, and includes a transition metal oxide.

According to another aspect of the present disclosure, there is provided A magnetic memory device comprising a lower electrode on a substrate, an upper electrode on the substrate and a magnetic tunnel junction element between the lower electrode and the upper electrode, wherein the magnetic tunnel junction element includes a first seed layer pattern, a second seed layer pattern, a pinned layer pattern, a tunnel barrier layer pattern, a free layer pattern, an oxide layer pattern, and a capping layer pattern that are stacked on the lower electrode, the first seed layer pattern is in direct contact with the lower electrode, and includes at least one oxide of molybdenum (Mo), nickel (Ni), zirconium (Zr), hafnium (Hf), rhenium (Re), magnesium (Mg), or tungsten (W), and the second seed layer pattern includes at least one of ruthenium (Ru), hafnium (Hf), zirconium (Zr), titanium (Ti), rhenium (Re), magnesium (Mg), cobalt (Co), nickel chromium (NiCr), or platinum (Pt).

### BRIEF DESCRIPTION OF DRAWINGS

The above and other aspects and features of the present disclosure will become more apparent by describing in detail embodiments thereof with reference to the attached drawings, in which:

FIG. 1 is an exemplary block diagram of a magnetic memory device according to some embodiments.

FIG. 2 is an exemplary circuit diagram for explaining a cell array of the magnetic memory device according to some embodiments.

FIG. 3 is a schematic cross-sectional view for explaining a magnetic tunnel junction element of a magnetic memory device according to some embodiments.

FIG. 4 is a schematic cross-sectional view for explaining a magnetic tunnel junction element of a magnetic memory device according to another embodiment.

FIG. 5 is a schematic cross-sectional view for explaining a magnetic tunnel junction element of a magnetic memory device according to another embodiment.

FIG. 6 is a schematic cross-sectional view for explaining a magnetic memory device according to some embodiments.

FIGS. 7 to 12 are intermediate step diagrams for explaining the method for fabricating the magnetic memory device according to some embodiments.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

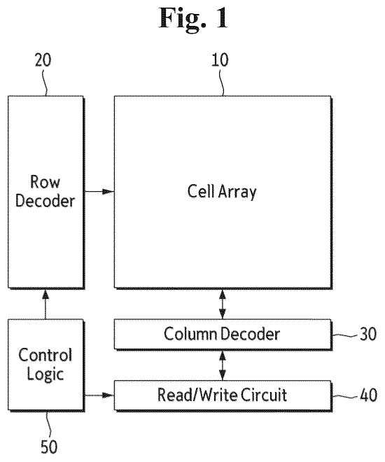

FIG. 1 is an exemplary block diagram of a magnetic memory device according to some embodiments.

Referring to FIG. 1, a magnetic memory device according to some embodiments includes a cell array 10, a row decoder 20, a column decoder 30, a read/write circuit 40, and a control logic 50.

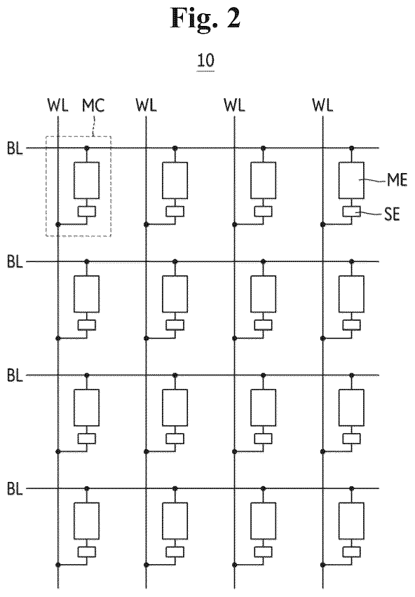

The cell array 10 may include a plurality of word lines and a plurality of bit lines. Memory cells may be connected to a point at which the word lines and the bit lines intersect each other. The cell array 10 will be described below in more detail in the description of FIG. 2.

The row decoder 20 may be connected to the cell array 10 through the word lines. The row decoder 20 may decode an address that is input from the outside to select one of the plurality of word lines.

The column decoder 30 may be connected to the cell array 10 through the bit lines. The column decoder 30 may decode an address that is input from the outside to select one of the plurality of bit lines. The bit line selected by the column decoder 30 may be connected to the read/write circuit 40.

The read/write circuit 40 may provide a bit line bias for accessing a selected memory cell in accordance with the control of the control logic 50. For example, the read/write circuit 40 may provide a bit line bias to the selected bit line to write or read the input data to the memory cell.

The control logic 50 may output control signals for controlling the magnetic memory device in accordance with a command signal provided from the outside. The control signals that are output from the control logic 50 may control the read/write circuit 40.

FIG. 2 is an exemplary circuit diagram for explaining a cell array of the magnetic memory device according to some embodiments.

Referring to FIG. 2, the cell array 10 includes a plurality of bit lines BL, a plurality of word lines WL, and a plurality of unit memory cells MC.

The word lines WL may extend in a first direction. The bit lines BL may extend in a second direction intersecting the first direction, and intersect the word lines WL.

The unit memory cells MC may be arranged in a two-dimensional (planar) array or a three-dimensional (stacked) configuration. Each unit memory cell MC may be connected to intersections between the word lines WL and the bit lines BL that intersect each other. Thus, each unit memory cell MC connected to the word lines WL may be connected to a read/write circuit (e.g., 40 of FIG. 1) by the bit lines BL. Each unit memory cell MC may include a magnetic tunnel junction element ME and a selection element SE, which together enable selective read and write operations.

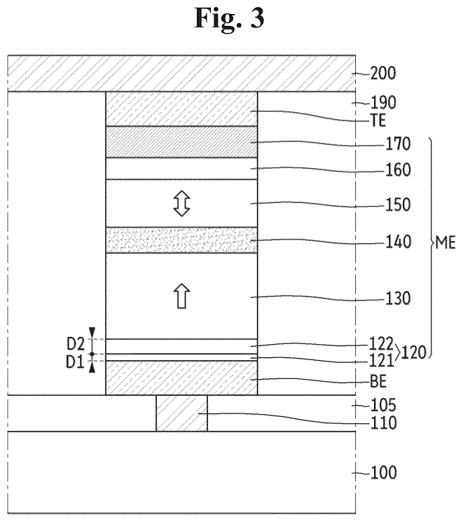

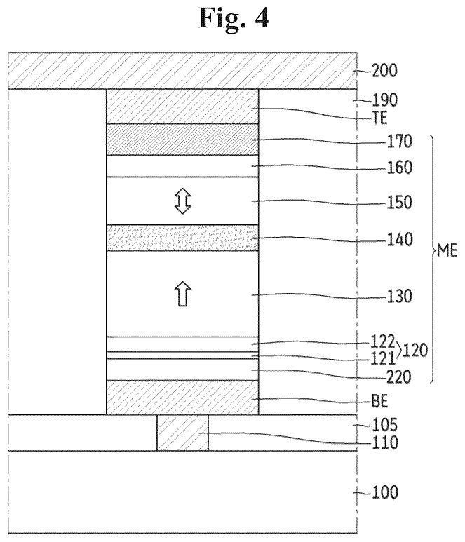

The magnetic tunnel junction element ME may be connected between the bit line BL and the selection element SE, and the selection element SE may be connected between the magnetic tunnel junction element ME and the word line WL. In operation, the selection element SE may control access to the magnetic tunnel junction element ME, enabling current to flow only during read or write operations. The magnetic tunnel junction element ME may include a pinned layer, a free layer, and a tunnel barrier layer. The magnetic tunnel junction element ME will be described in more detail below in the description of FIGS. 3 and 4.

The selection element SE may be configured to selectively control the flow of charge passing through the magnetic tunnel junction element ME. For example, the selection element SE may include at least one of a diode, a positive-negative-positive (PNP) bipolar transistor, a negative-positive-negative (NPN) bipolar transistor, a n-type metal-oxide semiconductor (NMOS) field effect transistor, and a p-type metal-oxide semiconductor (PMOS) field effect transistor. When the selection element SE includes a bipolar transistor or a MOS field effect transistor that is a three-terminal element, an additional wiring (e.g., a source line) may be connected to the selection element SE.

FIG. 3 is a schematic cross-sectional view for explaining a magnetic tunnel junction element of a magnetic memory device according to some embodiments.

Referring to FIG. 3, the magnetic tunnel junction element ME of the magnetic memory device according to some embodiments may include a seed layer pattern 120, a pinned layer pattern 130, a tunnel barrier layer pattern 140, a free layer pattern 150, an oxide layer pattern 160, and a capping layer pattern 170. The seed layer pattern 120 may initiate or control the growth and crystalline orientation of subsequent layers. The pinned layer pattern 130 may include a magnetic layer with a fixed (or pinned) magnetization direction, and may form part of a magnetic tunnel junction. The free layer pattern 150 may include a magnetic layer whose magnetization direction may change in response to an external magnetic field or spin current. The magnetization orientation of the free layer pattern 150 relative to that of the pinned layer pattern 130 determines the memory state, represented as 0 or 1. The capping layer pattern 170 may operate as a protective layer to prevent oxidation or damage and may help tune magnetic or structural properties. The oxide layer pattern 160 includes an oxide material that may form tunneling barriers and function as diffusion barriers or seed control layers.

The seed layer pattern 120 may be provided as a seed layer of the pinned layer pattern 130 to be described below. The seed layer pattern 120 may include a first seed layer pattern 121 and a second seed layer pattern 122. The seed layer pattern 120 may be in direct contact with the lower electrode pattern BE. Specifically, the first seed layer pattern 121 may be in direct contact with the lower electrode pattern BE.

A thickness D1 of the first seed layer pattern 121 is less than a thickness D2 of the second seed layer pattern 122. For example, the thickness D1 of the first seed layer pattern 121 may be 30% or less of the thickness D2 of the second seed layer pattern 122. The thickness D1 of the first seed layer pattern 121 may be 10 Å (angstrom) or more and 15 Å or less. For example, when the thickness D2 of the second seed layer pattern 122 is 50 Å, the thickness D1 of the first seed layer pattern 121 may be 15 Å.

Each of the first seed layer pattern 121 and the second seed layer pattern 122 may include different materials from each other. The first seed layer pattern 121 may be amorphous. The first seed layer pattern 121 may include an oxide having a low resistivity. For example, the resistivity of the material included in the first seed layer pattern 121 may be about 30% or less of the resistivity of the material included in the tunnel barrier layer pattern 140 to be described below. The first seed layer pattern 121 may include a transition metal oxide, which is a compound composed of oxygen and a transition metal. For example, the first seed layer pattern 121 may include at least one oxide of molybdenum (Mo), nickel (Ni), zirconium (Zr), hafnium (Hf), rhenium (Re), magnesium (Mg), and tungsten (W), such as molybdenum oxide (MoOx), nickel oxide (NiOx), zirconium oxide (ZrOx), hafnium oxide (HfOx), rhenium oxide (ReOx), magnesium oxide (MgOx), and tungsten oxide (WOx).

The second seed layer pattern 122 may include at least one of ruthenium (Ru), hafnium (Hf), zirconium (Zr), titanium (Ti), rhenium (Re), magnesium (Mg), cobalt (Co), nickel chromium (NiCr), and platinum (Pt).

For example, if the pinned layer pattern 130 includes a material having an L1₀ type crystal structure, the second seed layer pattern 122 may include a conductive metal nitride having a face-centered cubic crystal structure (FCC crystal structure or sodium chloride (NaCl) crystal structure) (e.g., titanium nitride, tantalum nitride, chrome nitride or vanadium nitride). If the pinned layer pattern 130 has a high density hexagonal crystal structure, the second seed layer pattern 122 may include a conductive material having a high density hexagonal crystal structure (e.g., ruthenium).

Although the second seed layer pattern 122 is shown as a single film in FIG. 3, it may include a multi-layer thin film in which different non-magnetic metals are stacked. For example, the second seed layer pattern 122 may include a first non-magnetic seed layer and a second non-magnetic seed layer that are stacked in sequence. The first non-magnetic seed layer may include, but is not limited to, tantalum (Ta), and the second non-magnetic seed layer may include platinum (Pt).

The pinned layer pattern 130 may have a pinned magnetization direction. For example, the magnetization direction of the pinned layer pattern 130 may be pinned regardless of the program current passing therethrough.

The pinned layer pattern 130 may include a ferromagnetic material. For example, the pinned layer pattern 130 may include, but is not limited to, at least one of an amorphous rare earth element alloy; a multi-layer thin film in which a ferromagnetic metal (FM) and a nonmagnetic metal (NM) are alternately stacked; an alloy having an L1₀ type crystal structure; a cobalt-based alloy; and combinations thereof.

The amorphous rare earth element alloy may include, for example, alloys such as TbFe, TbCo, TbFeCo, DyTbFeCo, and GdTbCo. The multi-layer thin film in which the ferromagnetic metal and the non-magnetic metal are alternately stacked may include, for example, multi-layer thin films such as Co/Pt, Co/Pd, CoCr/Pt, Co/Ru, Co/Os, Co/Au, and Ni/Cu. The alloy having the L1₀ type crystal structure may include, for example, alloys such as Fe₅₀Pt₅₀, Fe₅₀Pd₅₀, Co₅₀Pt₅₀, Fe₃₀Ni₂₀Pt₅₀, and Co₃₀Ni₂₀Pt₅₀. The cobalt-based alloy may include, for example, alloys such as CoCr, CoPt, CoCrPt, CoCrTa, CoCrPtTa, CoCrNb, and CoFeB. As an example, the pinned layer pattern 130 may include a CoFeB film.

In some embodiments, the pinned layer pattern 130 may have perpendicular magnetic anisotropy (PMA). That is, the pinned layer pattern 130 may have a magnetization easy axis in a direction perpendicular to an extending direction of the pinned layer pattern 130 (or a thickness direction of the pinned layer pattern 130). A unidirectional arrow of the pinned layer pattern 130 of FIG. 3 indicates that the magnetization direction of the pinned layer pattern 130 is pinned vertically.

The free layer pattern 150 may have variable magnetization directions. For example, the magnetization direction of the free layer pattern 150 may be variable depending on the program current passing through it. In some embodiments, the magnetization direction of the free layer pattern 150 may change by a spin transfer torque (STT).

The free layer pattern 150 may include at least one magnetic element. The magnetic element of the free layer pattern 150 may include, for example, but is not limited to, at least one of cobalt (Co), iron (Fe) and nickel (Ni).

In some embodiments, the free layer pattern 150 may include at least one magnetic element and boron (B). For example, the free layer pattern 150 may include at least one of cobalt (Co), iron (Fe) and nickel (Ni), and boron (B). As an example, the free layer pattern 150 may include a CoFeB film. In some other embodiments, the free layer pattern 150 may not include boron (B). As an example, the free layer pattern 150 may include a CoFe film.

In some embodiments, the free layer pattern 150 may have a perpendicular magnetic anisotropy (PMA). That is, the free layer pattern 150 may have a magnetization easy axis in a direction perpendicular to the extending direction of the free layer pattern 150 (or the thickness direction of the free layer pattern 150). A bidirectional arrow of the free layer pattern 150 of FIG. 3 indicates that the magnetization direction of the free layer pattern 150 may be magnetized to be parallel or antiparallel to the magnetization direction of the pinned layer pattern 130.

In some embodiments, the free layer pattern 150 may include magnetic elements that may be combined with oxygen atoms to induce an interfacial perpendicular magnetic anisotropy (i-PMA). The magnetic element may be, for example, iron (Fe). As an example, the free layer pattern 150 may include a CoFeB film or a CoFe film.

In some embodiments, the free layer pattern 150 may be amorphous. As an example, the free layer pattern 150 may include an amorphous CoFeB film or an amorphous CoFe film.

The tunnel barrier layer pattern 140 may be interposed between the pinned layer pattern 130 and the free layer pattern 150. The tunnel barrier layer pattern 140 may be provided as an insulated tunnel barrier that generates quantum mechanical tunneling between the pinned layer pattern 130 and the free layer pattern 150.

The tunnel barrier layer pattern 140 may include, for example, but is not limited to, at least one of magnesium oxide (MgO), aluminum oxide (Al₂O₃), silicon oxide (SiO₂), tantalum oxide (Ta₂O₅), silicon nitride (SiN), aluminum nitride (AlN), and combinations thereof. As an example, the tunnel barrier layer pattern 140 may include a magnesium oxide film (MgO film) having a face-centered cubic (FCC) crystal structure or a sodium chloride (NaCl) crystal structure.

The magnetic tunnel junction element, which includes the pinned layer pattern 130, the tunnel barrier layer pattern 140 and the free layer pattern 150, may function as a variable resistance element that may switch between two resistance states by an electrical signal (e.g., program current) applied thereto. For example, when the magnetization direction of the pinned layer pattern 130 and the magnetization direction of the free layer pattern 150 are parallel to each other, the magnetic tunnel junction element has a low resistance value, which may be stored as data “0”. In contrast, when the magnetization direction of the pinned layer pattern 130 and the magnetization direction of the free layer pattern 150 are antiparallel to each other, the magnetic tunnel junction element has a high resistance value, which may be stored as data “1”.

In some embodiments, the pinned layer pattern 130, the tunnel barrier layer pattern 140, and the free layer pattern 150 may be stacked sequentially on the substrate 100. The substrate 100 may be, for example, but is not limited to, a silicon substrate, a gallium arsenide substrate, a silicon germanium substrate, a ceramic substrate, a quartz substrate, a display glass substrate or the like, and may be a Semiconductor On Insulator (SOI) substrate.

The oxide layer pattern 160 may be spaced apart from the tunnel barrier layer pattern 140 with the free layer pattern 150 interposed therebetween. For example, the oxide layer pattern 160 may be stacked on an upper side of the free layer pattern 150. In some embodiments, the oxide layer pattern 160 may be in contact with the free layer pattern 150.

The oxide layer pattern 160 may include a metal oxide. For example, the oxide layer pattern 160 may include tantalum (Ta), magnesium (Mg), iron (Fe), cobalt (Co), tungsten (W), iridium (Ir), ruthenium (Ru), molybdenum (Mo), hafnium (Hf), zirconium (Zr), niobium (Nb), aluminum (Al), manganese (Mn), and alloys thereof. Although the oxide layer pattern 160 is only shown as being a single film in FIG. 3, this is merely an example, and the oxide layer pattern 160 may include multiple films including different metal oxides from each other.

The oxide layer pattern 160 may induce the magnetic anisotropy at the interface with the free layer pattern 150 to improve the magnetic anisotropy of the free layer pattern 150. For example, oxygen atoms supplied from the oxide layer pattern 160 may induce interfacial perpendicular magnetic anisotropy (i-PMA) at the interface with the free layer pattern 150, thereby improving the perpendicular magnetic anisotropy (PMA) of the free layer pattern 150.

In some embodiments, the oxide layer pattern 160 may have an oxygen concentration gradient. For example, as shown in FIG. 4, the oxygen concentration of the oxide layer pattern 160 may decrease from the capping layer pattern 170 toward the free layer pattern 150.

When the free layer pattern 150 includes boron (B), the oxide layer pattern 160 may further include boron (B). For example, the oxide layer pattern 160 may include metal borate. The metal borate may include, for example, at least one of TaBO, MgBO, FeBO, CoBO, CoFeBO, IrBO, RuBO, MoBO, HfBO, ZrBO and NbO. As an example, the oxide layer pattern 160 may include a TaBO film.

When the free layer pattern 150 does not include boron (B), the oxide layer pattern 160 may also be free of boron (B). For example, the oxide layer pattern 160 may include at least one of TaO, MgO, WO, IrO, RuO, MoO, HfO and ZrO. As an example, the oxide layer pattern 160 may include a TaO film.

The capping layer pattern 170 may be spaced apart from the free layer pattern 150 with the oxide layer pattern 160 interposed therebetween. For example, the capping layer pattern 170 may be stacked on the upper side of the oxide layer pattern 160. In some embodiments, the capping layer pattern 170 may be in contact with the oxide layer pattern 160.

The capping layer pattern 170 may include a metal or a metal nitride. The metal may include, for example, but is not limited to, at least one of tantalum (Ta), magnesium (Mg), tungsten (W), iridium (Ir), ruthenium (Ru), molybdenum (Mo), hafnium (Hf) and zirconium (Zr). The metal nitride may include, for example, but is not limited to, at least one of titanium nitride (TiN), tantalum nitride (TaN), aluminum nitride (AlN), zirconium nitride (ZrN), niobium nitride (NbN), molybdenum nitride (MoN), and combinations thereof. The capping layer pattern 170 may protect the magnetic tunnel junction element ME in a subsequent process after the capping layer pattern 170 is formed.

In some embodiments, a part of the capping layer pattern 170 adjacent to the oxide layer pattern 160 may include oxygen. When the free layer pattern 150 includes boron (B), the capping layer pattern 170 may further include boron (B). For example, the capping layer pattern 170 may include metal boride. The metal boride may include, for example, at least one of TaB, MgB, CoFeB, IrB, RuB, MoB, HfB and ZrB. As an example, the capping layer pattern 170 may include a TaB film.

When the free layer pattern 150 does not include boron (B), the capping layer pattern 170 may also be free of boron (B). For example, the capping layer pattern 170 may include at least one of tantalum (Ta), magnesium (Mg), tungsten (W), iridium (Ir), ruthenium (Ru), molybdenum (Mo), hafnium (Hf) and zirconium (Zr). As an example, the capping layer pattern 170 may include a Ta film.

The magnetic tunnel junction element ME may be connected to the selection element (e.g., SE of FIG. 2) on the substrate 100. For example, a first interlayer insulating film 105, a contact plug 110 and a lower electrode pattern BE may be formed on the substrate 100.

The first interlayer insulating film 105 may cover the upper side of the substrate 100. The first interlayer insulating film 105 may include, for example, but is not limited to, silicon oxide, silicon oxynitride, or the like.

The contact plug 110 penetrates the first interlayer insulating film 105, and may be connected to the selection element (e.g., SE of FIG. 2) on the substrate 100. The contact plug 110 may include a conductive material, for example, but is not limited to, at least one of a doped semiconductor material (e.g., doped silicon), a metal (e.g., tungsten, aluminum, copper, titanium, and/or tantalum), a conductive metal nitride (e.g., titanium nitride, tantalum nitride and/or tungsten nitride) and a metal-semiconductor compound (e.g., metal silicide).

A lower electrode pattern BE may be formed on the first interlayer insulating film 105 and the contact plug 110. The lower electrode pattern BE may be electrically connected to the contact plug 110. The magnetic tunnel junction element ME may be formed on the lower electrode pattern BE. For example, the lower electrode pattern BE may be interposed between the contact plug 110 and the magnetic tunnel junction element ME. Accordingly, the magnetic tunnel junction element ME may be electrically connected to the selection element (e.g., SE of FIG. 2) on the substrate 100. The lower electrode pattern BE may include, for example, but is not limited to, a conductive metal (e.g., titanium or tantalum) or a conductive metal nitride (e.g., titanium nitride or tantalum nitride).

The magnetic tunnel junction element ME may be connected to a conductive line 200 on the magnetic tunnel junction element ME. For example, an upper electrode pattern TE, the second interlayer insulating film 190, and the conductive line 200 may be formed on the magnetic tunnel junction element ME.

The upper electrode pattern TE may be formed on the magnetic tunnel junction element ME. For example, the upper electrode pattern TE may be stacked on an upper side of the capping layer pattern 170. The upper electrode pattern TE may include, for example, but is not limited to, a conductive metal or a conductive metal nitride. For example, the upper electrode pattern TE may include at least one of ruthenium (Ru), tantalum (Ta), and nitrides thereof.

A second interlayer insulating film 190 may be formed on the first interlayer insulating film 105. The second interlayer insulating film 190 may cover the first interlayer insulating film 105, the lower electrode pattern BE, the magnetic tunnel junction element ME, and the upper electrode pattern TE. The second interlayer insulating film 190 may include, for example, but is not limited to, silicon oxide, silicon oxynitride or the like.

The conductive line 200 may be formed on the second interlayer insulating film 190 and the upper electrode pattern TE. The conductive line 200 may be electrically connected to the upper electrode pattern TE. For example, the upper electrode pattern TE may be interposed between the magnetic tunnel junction element ME and the conductive line 200. Accordingly, the magnetic tunnel junction element ME may be electrically connected to the conductive line 200. In some embodiments, conductive line 200 may be provided as a bit line BL of FIG. 2.

In a high-temperature process for fabricating a magnetic memory device including a magnetic tunnel junction element, a reduction in the crystallinity of the seed layer may occur. For example, in a high-temperature process such as a heat treatment process and/or a back end of line (BEOL) process, tantalum (Ta) atoms included in the lower electrode pattern BE may diffuse toward the seed layer. This diffusion may degrade or decrease the crystallinity of the seed layer and lead to deterioration in the dispersion of composition of the magnetic memory device. For example, the crystallinity of the seed layer may decrease, and the composition dispersion of the pinned layer pattern 130 may deteriorate.

However, in the magnetic memory device according to some embodiments, since the magnetic tunnel junction element ME includes the seed layer pattern 120, the pinned layer pattern 130, the tunnel barrier layer pattern 140, the free layer pattern 150, the oxide layer pattern 160, and the capping layer pattern 170, it is possible to prevent or suppress the tantalum (Ta) atoms contained in the lower electrode pattern TE from diffusing toward the upper electrode pattern TE.

As an example, as the first seed layer pattern 121 is disposed between the lower electrode pattern BE and the second seed layer pattern 122, it is possible to prevent or suppress the tantalum (Ta) atoms contained in the lower electrode pattern BE from diffusing. Specifically, since the first seed layer pattern 121 includes at least one oxide among molybdenum (Mo), nickel (Ni), zirconium (Zr), hafnium (Hf), rhenium (Re), magnesium (Mg) and tungsten (Tb) having a resistivity of about 30% or less of the material included in the tunnel barrier layer pattern 140, it is possible to prevent or suppress tantalum (Ta) atoms contained in the lower electrode pattern BE from diffusing. As a result, it is possible to provide a magnetic memory device in which the dispersion is improved, and product reliability and performance are enhanced.

FIG. 4 is a schematic cross-sectional view for explaining a magnetic tunnel junction element of a magnetic memory device according to another embodiment. For convenience of explanation, FIG. 4 will mainly explain differences from those explained in FIG. 3.

Referring to FIG. 4, the magnetic tunnel junction element ME of the magnetic memory device according to another embodiment may include a buffer layer pattern 220, a seed layer pattern 120, a pinned layer pattern 130, a tunnel barrier layer pattern 140, a free layer pattern 150, an oxide layer pattern 160, and a capping layer pattern 170.

The buffer layer pattern 220 may be disposed between the first seed layer pattern 121 and the lower electrode pattern BE. The buffer layer pattern 220 may include, but is not limited to, tantalum oxide (TaO) or tantalum nitride (TaN). The buffer layer pattern 220 may prevent tantalum (Ta) atoms included in the lower electrode pattern BE from diffusing toward the seed layer.

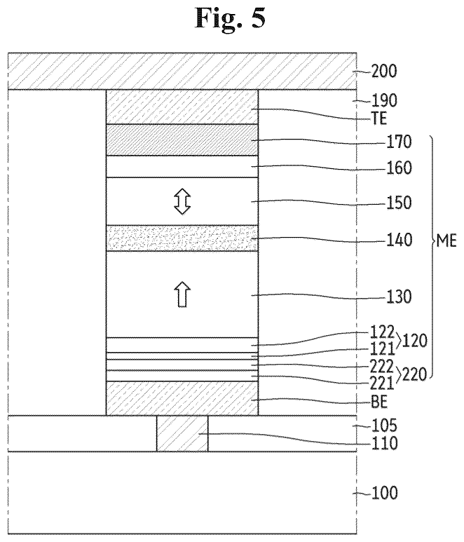

FIG. 5 is a schematic cross-sectional view for explaining a magnetic tunnel junction element of a magnetic memory device according to another embodiment.

Referring to FIG. 5, the magnetic tunnel junction element ME of the magnetic memory device according to another embodiment may include a first buffer layer pattern 221, a second buffer layer pattern 222, a seed layer pattern 120, a pinned layer pattern 130, a tunnel barrier layer pattern 140, a free layer pattern 150, an oxide layer pattern 160, and a capping layer pattern 170.

The buffer layer pattern 220 may include a first buffer layer pattern 221 and a second buffer layer pattern 222. The first buffer layer pattern 221 may be disposed between the lower electrode pattern BE and the second buffer layer pattern 222. The first buffer layer pattern 221 and the second buffer layer pattern 222 may include different materials from each other. For example, when the first buffer layer pattern 221 includes tantalum nitride (TaN), the second buffer layer pattern 222 may include, but is not limited to, tantalum oxide (TaO). The first buffer layer pattern 221 and the second buffer layer pattern 222 may prevent tantalum (Ta) atoms included in the lower electrode pattern BE from diffusing toward the seed layer.

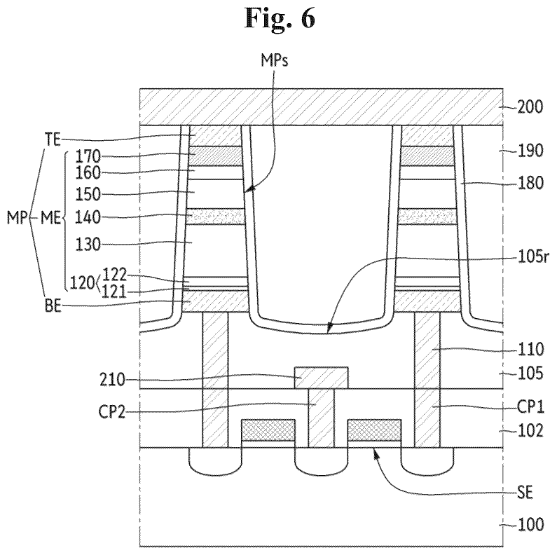

FIG. 6 is a schematic cross-sectional view for explaining a magnetic memory device according to some embodiments. For convenience of explanation, FIG. 6 will mainly escribe differences from those explained in FIGS. 1 to 5.

Referring to FIG. 6, the magnetic memory device according to some embodiments may include a selection element SE, a source line 210, a plurality of memory cells MP, and a conductive line 200.

The selection element SE may be formed on the substrate 100. Although the selection element SE is shown as being a MOS field effect transistor, this is merely an example. As another example, a diode or a bipolar transistor may constitute the selection element SE.

The source line 210 may be formed on the substrate 100. The source line 210 may be electrically connected to the selection element SE. For example, a third interlayer insulating film 102 that covers the selection element SE may be formed on the substrate 100. The source line 210 may be formed on the third interlayer insulating film 102. Also, a source contact CP2 which penetrates the third interlayer insulating film 102 and connects the selection element SE and the source line 210 may be formed. Although only two adjacent selection elements SE are shown to share one source line 210, this is merely an example. As another example, it goes without saying that source lines 210 corresponding to each of the selection elements SE may be provided.

A plurality of memory cells MP may be formed on the substrate 100. Each memory cell MP may be electrically connected to the selection element SE. For example, a first interlayer insulating film 105 that covers the source line 210 may be formed on the third interlayer insulating film 102. The memory cells MP may be formed on the first interlayer insulating film 105. Also, a landing contact CP1 that penetrates the third interlayer insulating film 102 may be formed, and a contact plug 110 that penetrates the first interlayer insulating film 105 and connects the landing contact CP1 and each memory cell MP may be formed.

Each memory cell MP may include a lower electrode pattern BE, a magnetic tunnel junction element ME, and an upper electrode pattern TE. The magnetic tunnel junction element ME may include at least one of the magnetic tunnel junction elements ME explained above using FIGS. 1 to 5. As an example, the magnetic tunnel junction element ME may include the seed layer pattern 120, the pinned layer pattern 130, the tunnel barrier layer pattern 140, the free layer pattern 150, the oxide layer pattern 160, and the capping layer pattern 170 explained above using FIG. 3.

In some embodiments, a capping liner 180 may be formed to cover each memory cell MP. For example, the capping liner 180 may conformally extend along the profile of the upper side of the first interlayer insulating film 105 and the profile of the side faces of each memory cell MP. The second interlayer insulating film 190 may be stacked on the capping liner 180.

The capping liner 180 may be provided as a protective layer that protects the memory cells MP from moisture or oxidation. For example, the capping liner 180 may prevent degradation of the characteristics of the magnetic tunnel junction element ME (e.g., a retention, coercivity (Hc), a resistance-area multiplication (RA), a TMR ratio (Tunneling Magnetoresistance ratio, etc.) due to moisture or oxidation. The capping liner 180 may include, for example, but is not limited to, a silicon nitride film.

In some embodiments, the upper part of the first interlayer insulating film 105 may include a recess 105r. The recess 105r may be formed inside the first interlayer insulating film 105 between the memory cells MP. The recess 105r may be formed by removing a part of the upper part of the first interlayer insulating film 105 in the process of patterning of the memory cells MP. In some embodiments, a part of the capping liner 180 may extend along the recess 105r.

The conductive line 200 may be formed on the second interlayer insulating film 190 and the memory cells MP. The conductive line 200 may be electrically connected to a plurality of memory cells MP arranged along the direction in which conductive line 200 extends. In some embodiments, the conductive line 200 may be provided as the bit line BL of FIG. 2.

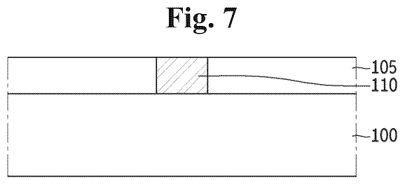

FIGS. 7 to 12 are intermediate step diagrams for explaining the method for fabricating the magnetic memory device according to some embodiments. For convenience of explanation, repeated parts of contents explained above using FIGS. 7 to 12 will be briefly explained or omitted.

Referring to FIG. 7, the first interlayer insulating film 105 and the contact plug 110 are formed on the substrate 100.

For example, the first interlayer insulating film 105 may be formed on the substrate 100. Subsequently, a contact plug 110 which penetrates the first interlayer insulating film 105 and is connected to the selection element (e.g., SE of FIG. 2) on the substrate 100 may be formed.

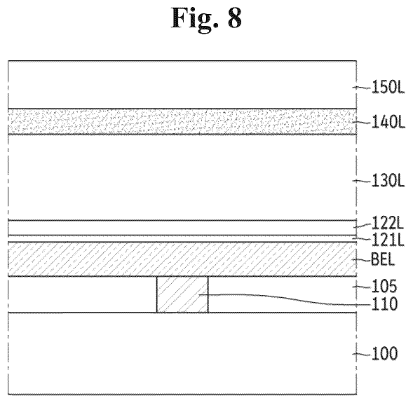

Referring to FIG. 8, a lower electrode layer BEL, a first seed layer 121L, a second seed layer 122L, a pinned layer 130L, a tunnel barrier layer 140L and a free layer 150L are formed on the first interlayer insulating film 105 and the contact plug 110.

For example, a lower electrode layer BEL connected to the contact plug 110 may be formed on the first interlayer insulating film 105. The first seed layer 121L, the second seed layer 122L, the pinned layer 130L, the tunnel barrier layer 140L and the free layer 150L may be sequentially stacked on the lower electrode layer BEL. Each of the first seed layer 121L, the second seed layer 122L, the pinned layer 130L, the tunnel barrier layer 140L and the free layer 150L may correspond to the first seed layer pattern 121, the second seed layer pattern 122, the pinned layer pattern 130, the tunnel barrier layer pattern 140 and the free layer pattern 150 explained above using FIG. 3. As an example, the pinned layer pattern 130 may include a CoFeB film, the tunnel barrier layer pattern 140 may include a MgO film, and the free layer pattern 150 may include a CoFeB film.

Each of the first seed layer 121L, the second seed layer 122L, the pinned layer 130L, the tunnel barrier layer 140L and the free layer 150L may be formed by, but are not limited to, a physical vapor deposition (PVD) (e.g., a sputtering process), a chemical vapor deposition (CVD) process or an atomic layer deposition (ALD) process.

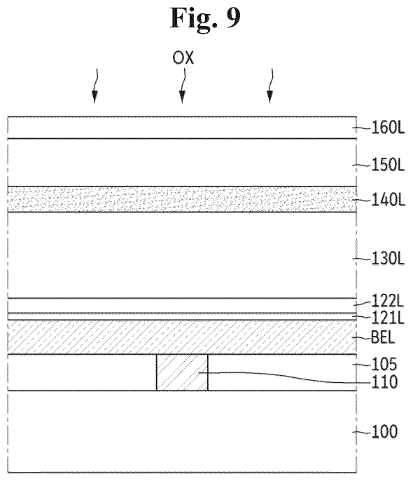

Referring to FIG. 9, an oxide layer 160L is formed on the free layer 150L. For example, a preliminary oxidation layer is formed on the free layer 150L. The preliminary oxidation layer may include a metal. For example, the preliminary oxidation layer may include at least one of tantalum (Ta), magnesium (Mg), iron (Fe), cobalt (Co), tungsten (W), iridium (Ir), ruthenium (Ru), molybdenum (Mo), hafnium (Hf), zirconium (Zr), and Ni. Then, an oxidation process (OX) is performed on the preliminary oxidation layer. Accordingly, the oxide layer 160L including a metal oxide may be formed.

When the free layer 150L includes boron (B), the oxide layer 160L may further include boron (B). For example, the preliminary oxidation layer may include metal boride. The metal boride may include, for example, at least one of TaB, MgB, FeB, CoB, CoFeB, IrB, RuB, MoB, HfB and ZrB. As the oxidation process (OX) is performed on the preliminary oxidation layer including the metal boride, the oxide layer 160L including metal borate may be formed.

As another example, when the free layer 150L does not include boron (B), the oxide layer 160L may also be free of boron (B).

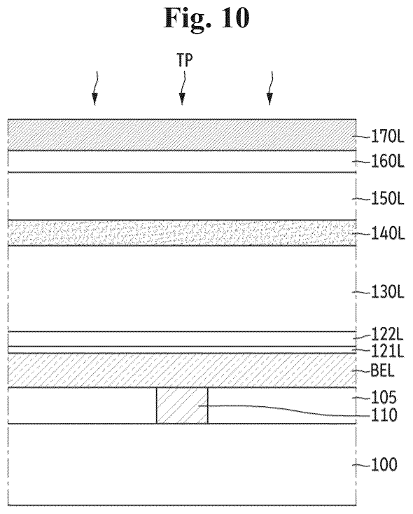

Referring to FIG. 10, a capping layer 170L is formed on the oxide layer 160L. The capping layer 170L may include a metal or a metal nitride. The metal may be, for example, but is not limited to, at least one of tantalum (Ta), magnesium (Mg), tungsten (W), iridium (Ir), ruthenium (Ru), molybdenum (Mo), hafnium (Hf) and zirconium (Zr). The metal nitride may include, for example, but is not limited to, at least one of titanium nitride (TiN), tantalum nitride (TaN), aluminum nitride (AlN), zirconium nitride (ZrN), niobium nitride (NbN), molybdenum nitride (MoN), and combinations thereof.

When the free layer 150L includes boron (B), the capping layer 170L may further include boron (B). For example, the capping layer 170L may include a metal boride. The metal boride may include at least one of, for example, TaB, MgB, CoFeB, IrB, RuB, MoB, HfB, and ZrB.

As another example, when the free layer 150L does not include boron (B), the capping layer 170L may also be free of boron (B).

After the capping layer 170L is formed, an annealing process (TP) may be performed. The annealing process (TP) may be performed at, for example, but is not limited to, 350° C. to 400° C.

As described above, the first seed layer 121L may prevent the diffusion of tantalum (Ta) atoms contained in the lower electrode pattern BE, by including an oxide with low resistivity. In other words, the diffusion of boron atoms due to the annealing process (TP) may be minimized by the first seed layer 121L. Accordingly, a method for fabricating a magnetic memory device in which dispersion is improved and product reliability and performance are enhanced may be provided.

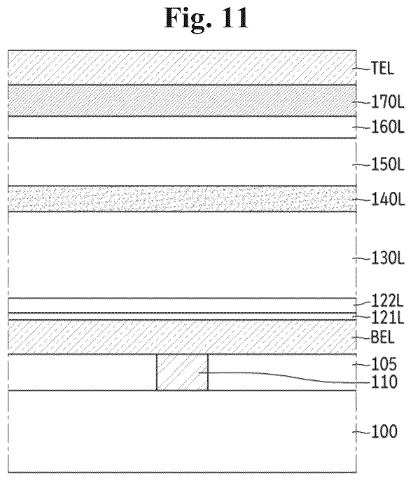

Referring to FIG. 11, an upper electrode layer TEL is formed on the capping layer 170L. The upper electrode layer TEL may include, for example, but is not limited to, a conductive metal or a conductive metal nitride. For example, the upper electrode layer TEL may include at least one of ruthenium (Ru), tantalum (Ta), and nitrides thereof.

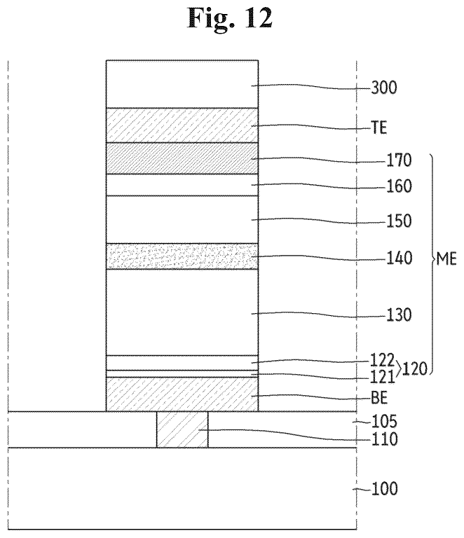

Referring to FIG. 12, the lower electrode pattern BE, the magnetic tunnel junction element ME, and the upper electrode pattern TE are formed.

For example, a mask pattern 300 may be formed on the upper electrode layer TEL of FIG. 11. Next, an etching process of using the mask pattern 300 as an etching mask may be performed. As the etching process is performed, the lower electrode layer BEL, the first seed layer 121L, the second seed layer 122L, the pinned layer 130L, the tunnel barrier layer 140L, the free layer 150L, the oxide layer 160L, the capping layer 170L, and the upper electrode layer TEL of FIG. 19 may be patterned. As a result, the lower electrode pattern BE, the seed layer pattern 120, the pinned layer pattern 130, the tunnel barrier layer pattern 140, the free layer pattern 150, the oxide layer pattern 160, the capping layer pattern 170, and the upper electrode pattern TE may be formed.

Next, referring to FIG. 3, a second interlayer insulating film 190 and a conductive line 200 are formed. Accordingly, the magnetic memory device explained above using FIG. 3 may be fabricated.

The present disclosure also provides an embodiment of a method of manufacturing a magnetic memory device, comprising forming a lower electrode layer on a substrate, sequentially stacking a first seed layer, a second seed layer, a pinned layer, a tunnel barrier layer, and a free layer on the lower electrode layer, forming a preliminary oxidation layer on the free layer, performing an oxidation process on the preliminary oxidation layer to form an oxidation layer, forming a capping layer on the oxidation layer and performing an annealing process and patterning the lower electrode layer to the capping layer to form a magnetic tunnel junction element.

Although embodiments of the present disclosure have been described above with reference to the accompanying drawings, the present disclosure may not be limited to embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that embodiments as described above are not restrictive but illustrative in all respects.

What is claimed is:

1. A magnetic memory device comprising:
a pinned layer pattern;
a free layer pattern;
a tunnel barrier layer pattern between the pinned layer pattern and the free layer pattern;
an oxide layer pattern spaced apart from the tunnel barrier layer pattern with the free layer pattern interposed between the oxide layer pattern and the tunnel barrier layer pattern;
a capping layer pattern spaced apart from the free layer pattern with the oxide layer pattern interposed between the capping layer pattern and the free layer pattern;
a first seed layer pattern spaced apart from the tunnel barrier layer pattern with the pinned layer pattern interposed between the first seed layer pattern and the tunnel barrier layer pattern; and
a second seed layer pattern between the pinned layer pattern and the first seed layer pattern,
wherein the first seed layer pattern comprises a transition metal oxide.

2. The magnetic memory device of claim 1, further comprising:
a buffer layer pattern spaced apart from the second seed layer pattern with the first seed layer pattern interposed between the buffer layer pattern and the first seed layer pattern.

3. The magnetic memory device of claim 2,
wherein the buffer layer pattern comprises a first buffer layer pattern and a second buffer layer pattern, and
the first buffer layer pattern and the second buffer layer pattern comprise tantalum (Ta).

4. The magnetic memory device of claim 3,
wherein the second buffer layer pattern is between the first buffer layer pattern and the first seed layer pattern,
the first buffer layer pattern comprises tantalum nitride (TaN), and
the second buffer layer pattern comprises tantalum oxide (TaO).

5. The magnetic memory device of claim 1,
wherein the first seed layer pattern includes at least one of molybdenum (Mo), nickel (Ni), zirconium (Zr), hafnium (Hf), rhenium (Re), magnesium (Mg), and tungsten (W).

6. The magnetic memory device of claim 1,
wherein the second seed layer pattern comprises at least one of ruthenium (Ru), hafnium (Hf), zirconium (Zr), titanium (Ti), rhenium (Re), magnesium (Mg), cobalt (Co), nickel chromium (NiCr), or platinum (Pt).

7. The magnetic memory device of claim 1,
wherein a thickness of the first seed layer pattern is greater than or equal to 10 Å and less than or equal to 15 Å.

8. The magnetic memory device of claim 1,
wherein the pinned layer pattern comprises a synthetic anti-ferromagnet (SAF).

9. A magnetic memory device comprising:
a lower electrode;
an upper electrode; and
a magnetic tunnel junction element between the lower electrode and the upper electrode,
wherein the magnetic tunnel junction element comprises a first seed layer pattern, a second seed layer pattern, a pinned layer pattern, a tunnel barrier layer pattern, a free layer pattern, an oxide layer pattern, and a capping layer pattern that are stacked on the lower electrode, and
the first seed layer pattern is in direct contact with the lower electrode, and comprises a transition metal oxide.

10. The magnetic memory device of claim 9, further comprising:
a buffer layer pattern between the lower electrode and the first seed layer pattern.

11. The magnetic memory device of claim 10,
wherein the buffer layer pattern comprises a first buffer layer pattern and a second buffer layer pattern,
wherein the first buffer layer pattern and the second buffer layer pattern comprise tantalum (Ta).

12. The magnetic memory device of claim 9,
wherein the first seed layer pattern comprises at least one of molybdenum (Mo), nickel (Ni), zirconium (Zr), hafnium (Hf), rhenium (Re), magnesium (Mg), or tungsten (W).

13. The magnetic memory device of claim 9,
wherein the second seed layer pattern comprises at least one of ruthenium (Ru), hafnium (Hf), zirconium (Zr), titanium (Ti), rhenium (Re), magnesium (Mg), cobalt (Co), nickel chromium (NiCr), or platinum (Pt).

14. The magnetic memory device of claim 9,
wherein a thickness of the first seed layer pattern is greater than or equal to 10 Å and is less than or equal to 15 Å.

15. The magnetic memory device of claim 9,
wherein the pinned layer pattern comprises a synthetic anti-ferromagnet (SAF).

16. The magnetic memory device of claim 9,
wherein the free layer pattern further comprises at least one of cobalt (Co), iron (Fe), or nickel (Ni).

17. A magnetic memory device comprising:
a lower electrode on a substrate;
an upper electrode on the substrate; and
a magnetic tunnel junction element between the lower electrode and the upper electrode,
wherein the magnetic tunnel junction element comprises a first seed layer pattern, a second seed layer pattern, a pinned layer pattern, a tunnel barrier layer pattern, a free layer pattern, an oxide layer pattern, and a capping layer pattern that are stacked on the lower electrode,
the first seed layer pattern is in direct contact with the lower electrode, and comprises at least one oxide of molybdenum (Mo), nickel (Ni), zirconium (Zr), hafnium (Hf), rhenium (Re), magnesium (Mg), or tungsten (W), and
the second seed layer pattern comprises at least one of ruthenium (Ru), hafnium (Hf), zirconium (Zr), titanium (Ti), rhenium (Re), magnesium (Mg), cobalt (Co), nickel chromium (NiCr), or platinum (Pt).

18. The magnetic memory device of claim 17, further comprising:
a buffer layer pattern spaced apart from the second seed layer pattern with the first seed layer pattern interposed between the buffer layer pattern and the second seed layer pattern.

19. The magnetic memory device of claim 18,
wherein the buffer layer pattern comprises a first buffer layer pattern and a second buffer layer pattern, and
the first buffer layer pattern and the second buffer layer pattern comprise tantalum (Ta).

20. The magnetic memory device of claim 17,
wherein a thickness of the first seed layer pattern is greater than or equal to 10 Å and is less than or equal to 15 Å.
